(19) United States
(12) Patent Application Publication
(10) Pub. No.: US 2021/0156031 A1
(43) Pub. Date: May 27, 2021

(54) APPARATUS FOR PROCESSING A SUBSTRATE

(71) Applicant: SAMSUNG ELECTRONICS CO., LTD., Suwon-si (KR)

(72) Inventors: Sungyong PARK, Suwon-si (KR); Mitsuaki KOMINO, Seongnam-si (KR); Kyungwon KANG, Yongin-si (KR); Wonguk SEO, Gunpo-si (KR); Sunggwang LEE, Hwaseong-si (KR); Sunghwan LEE, Yongin-si (KR)

(73) Assignee: SAMSUNG ELECTRONICS CO., LTD., Suwon-si (KR)

(21) Appl. No.: 16/932,194

(22) Filed: Jul. 17, 2020

(30) Foreign Application Priority Data
Nov. 25, 2019 (KR) 10-2019-0151835

(51) Int. Cl. C23C 16/52; C23C 16/56; G03F 7/16

(52) U.S. Cl. CPC C23C 16/52; C23C 16/56; H01L 21/0274; G03F 7/168; G03F 7/167

(57) ABSTRACT

An apparatus for processing a substrate may include a mixture bath, a plurality of reaction chambers and a control module. The mixture bath may be configured to receive a plurality of chemicals to form a mixture. Each of the reaction chambers may be configured to receive a respective substrate of a plurality of the substrates to be processed by the mixture. The control module may be configured to control supply of the mixture supplied from the mixing bath to the reaction chambers with a uniform concentration.

### CROSS-REFERENCE TO RELATED APPLICATION(S)

This application claims priority under 35 U.S.C. § 119 to Korean Patent Application No. 10-2019-0151835, filed on Nov. 25, 2019 in the Korean Intellectual Property Office, the contents of which are incorporated by reference herein in their entirety.

### BACKGROUND

### 1. Field

Example embodiments relate to an apparatus for processing a substrate, and more particularly, to an apparatus for hydrophobizing a surface of a semiconductor substrate to improve coatability of a photoresist film on the surface of the semiconductor substrate.

### 2. Description of Related Art

In an exposure process, a photoresist film may be formed on a surface of a semiconductor substrate. In order to improve coatability of the photoresist film on the surface of the semiconductor substrate, it may be required to hydrophobize the surface of the semiconductor substrate in a baking chamber using a hydrophobizing gas. The hydrophobizing gas may be formed by evaporating a hydrophobizing liquid using a carrier gas. Thus, a mixed gas of the hydrophobizing gas and the carrier gas may be applied to the surface of the semiconductor substrate to hydrophobize the surface of the semiconductor substrate.

In the related art, when a hydrophobizing process may be performed on a plurality of the baking chambers configured to receive the semiconductor substrates, the hydrophobizing gas may be present at different concentrations in each of the baking chambers. The different concentrations may cause a hydrophobization difference between the surfaces of the semiconductor substrate, i.e., a difference of contact angles. The different of the contact angles may result in a thickness difference between the photoresist films on the surfaces of the semiconductor substrate. As a result, the thickness difference between the photoresist films may act as an error of the exposure process.

### SUMMARY

Example embodiments provide an apparatus for processing substrates that may be capable of uniformly controlling concentrations of hydrophobizing gases supplied to baking chambers configured to receive the substrates.

According to an aspect of an example embodiment, there is provided an apparatus for processing a substrate, the apparatus including: a mixture bath configured to mix a plurality of chemicals to form a mixture; a plurality of reaction chambers, each reaction chamber of the plurality of reaction chambers being configured to receive a respective substrate from among a plurality of substrates to be processed by the mixture; and a control module configured to control supply of the mixture to the plurality of reaction chambers from the mixture bath with a uniform concentration.

According to an aspect of an example embodiment, there is provided an apparatus for processing a substrate, the apparatus including: a bubbler configured to evaporate a hydrophobizing solution using a carrier gas to form a mixture gas including a hydrophobizing gas and the carrier gas; a plurality of baking chambers configured to thermally treat a plurality of substrates to be hydrophobized by the hydrophobizing gas; a main line extended from the bubbler; a plurality of branch lines branched from the main line and connected to the plurality of baking chambers; and a control module configured to provide the hydrophobizing gas in the mixture gas flowing through the plurality of branch lines to the plurality of baking chambers with a uniform concentration.

According to an aspect of an example embodiment, there is provided an apparatus for processing a substrate, the apparatus including: a bubbler configured to evaporate a hexamethyldisilazane (HMDS) solution using a nitrogen gas to form a mixture gas including a HMDS gas and the nitrogen gas; a plurality of baking chambers configured to thermally treat a plurality of substrates to be hydrophobized by the HMDS gas; a main line extended from the bubbler; a plurality of branch lines branched from the main line and connected to the plurality of baking chambers; a mass flow controller (MFC) configured to measure a first flux of the nitrogen gas supplied to the bubbler; a plurality of mass flow meters (MFMs) arranged on the plurality of branch lines, the plurality of MFMs being configured to measure second fluxes of the mixture gas supplied to the plurality of baking chambers; a plurality of piezo valves arranged between the plurality of MFMs and the plurality of baking chambers; and a control module configured to control the plurality of piezo valves based on the first flux of the nitrogen gas measured by the MFC and the second fluxes of the mixture gas measured by the plurality of MFMs to provide the HMDS gas with a uniform concentration.

### BRIEF DESCRIPTION OF THE DRAWINGS

The above and other aspects of certain example embodiments of the present disclosure will be more apparent from the following description taken in conjunction with the accompanying drawings, in which:

FIG. 1 is a block diagram illustrating an apparatus for processing a substrate according to an example embodiment;

FIG. 2 is a block diagram illustrating an apparatus for processing a substrate according to an example embodiment;

FIG. 3 is a graph showing concentrations of an HMDS gas measured by a densitometer and a mass flow meter;

FIG. 4 is a block diagram illustrating an apparatus for processing a substrate according to an example embodiment;

FIG. 5A is a graph showing concentration of HMDS gases in comparison to temperature changes of a bubbler in accordance with the related art;

FIG. 5B is a graph showing concentration of HMDS gases in comparison to temperature changes of a bubbler according to an ex ample embodiment;

FIG. 6A is a graph showing concentration of HMDS gases in comparison to changes of a carrier gas in accordance with the related art apparatus;

FIG. 6B is a graph showing concentration of HMDS gases in comparison to changes of a carrier gas according to an example embodiment;

FIG. 7A is a graph showing concentration of HMDS gases in comparison to a surface height of a bubbler in accordance with the related art; and

FIG. 7B is a graph showing concentration of HMDS gases in comparison to a surface height of a bubbler according to an example embodiment.

### DETAILED DESCRIPTION

Hereinafter, example embodiments will be explained in detail with reference to the accompanying drawings.

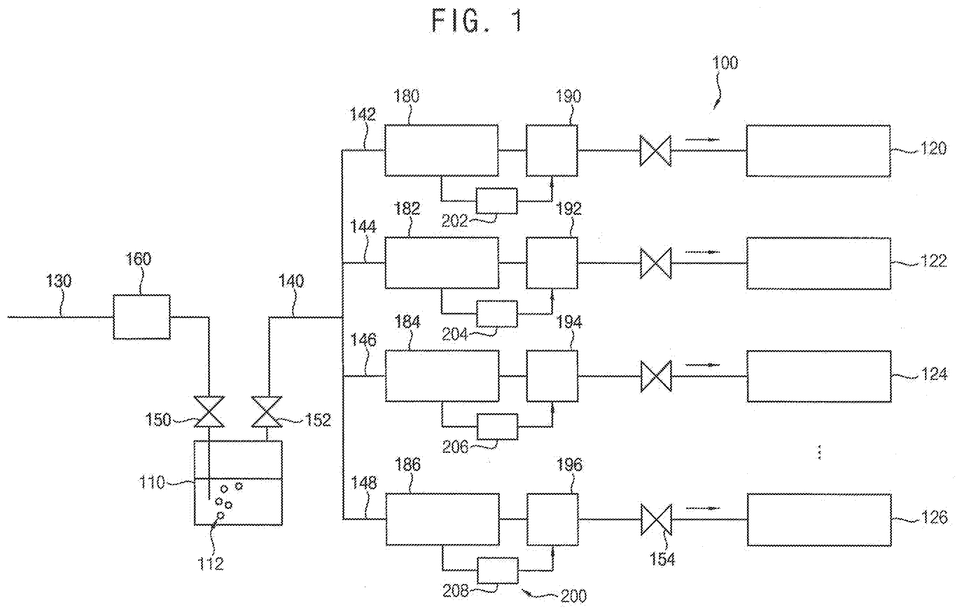

FIG. 1 is a block diagram illustrating an apparatus for processing a substrate in accordance with an example embodiment.

Referring to FIG. 1, an apparatus 100 for processing a substrate in accordance with example embodiments may include a mixture bath 110, first to fourth reaction chambers 120, 122, 124 and 126, a gas line 130, a main line 140 and first to fourth branch lines 142, 144, 146 and 148.

The mixture bath 110 may be configured to mix at least two chemicals with each other to form a mixture. In example embodiments, the apparatus 100 may include an apparatus for hydrophobizing a surface of a semiconductor substrate using a hydrophobizing gas. Thus, the chemicals may include a hydrophobizing solution and a carrier gas. The hydrophobizing solution may include a hexamethyldisilazane (HMDS) solution. The carrier gas may include a nitrogen gas. However, the hydrophobizing gas and the carrier gas may include other materials in place of the above-mentioned materials. Further, alternatively, the apparatus 100 may have functions for processing the semiconductor substrate using at least two chemicals used for manufacturing a semiconductor device.

In example embodiments, the mixture bath 110 may include a bubbler 112. The bubbler 112 may be configured to receive the hydrophobizing solution. The carrier gas may be supplied to the bubbler 112 through the gas line 130. The gas line 130 may be dipped into the hydrophobizing solution in the bubbler 112. An opening/closing valve 150 for controlling the carrier gas may be installed on the gas line 130. The bubbler 112 may evaporate the hydrophobizing solution using the carrier gas to form the hydrophobizing gas. Therefore, a mixture gas formed by the bubbler 112 may include the hydrophobizing gas and the carrier gas.

The first to fourth reaction chambers 120, 122, 124 and 126 may be configured to receive a plurality of the semiconductor substrates hydrophobized by the hydrophobizing gas, respectively. In other words, each one of the first to fourth reaction chambers 120, 122, 124 and 126 may receive a respective semiconductor substrate to be hydrophobized by the hydrophobizing gas. The first to fourth reaction chambers 120, 122, 124 and 126 may be vertically arranged. That is, the first to fourth reaction chambers 120, 122, 124 and 126 may be downwardly arranged to have different heights. Alternatively, the first to fourth reaction chambers 120, 122, 124 and 126 may be arranged on a substantially same plane to have a substantially same height.

As mentioned above, because the apparatus 100 may include the hydrophobizing apparatus, the first to fourth reaction chambers 120, 122, 124 and 126 may include baking chambers configured to thermally treat the semiconductor substrates. However, the first to fourth reaction chambers 120, 122, 124 and 126 may include other chambers used for manufacturing the semiconductor device using at least two chemicals. Further, in example embodiments, the apparatus 100 may include the four reaction chambers 120, 122, 124 and 126. Alternatively, the apparatus 100 may include two, three or at least five reaction chambers.

The main line 140 may be extended from the mixture bath 110. Thus, the mixture gas generated in the mixture bath 110 may flow through the main line 140. An opening/closing valve 152 for controlling the mixture gas may be installed on the main line 140.

The first to fourth branch lines 142, 144, 146 and 148 may be branched from the main line 140. The first to fourth branch lines 142, 144, 146 and 148 may be connected to the first to fourth reaction chambers 120, 122, 124 and 126, respectively. In example embodiments, because the reaction chambers 120, 122, 124 and 126 may be four, the branch lines 142, 144, 146 and 148 may also be four. Thus, the number of branch lines may be determined in accordance with the number of reaction chambers. Further, when the first to fourth reaction chambers 120, 122, 124 and 126 may be vertically arranged, the first to fourth branch lines 142, 144, 146 and 148 may also be vertically arranged to have different heights. In contrast, when the first to fourth reaction chambers 120, 122, 124 and 126 may be arranged on the same plane, the first to fourth branch lines 142, 144, 146 and 148 may also be arranged on the same plane to have a same height. Opening/closing valves 154 for controlling the mixture gas may be installed on the first to fourth branch lines 142, 144, 146 and 148, respectively.

The mixture gas flowing through the main line 140 may be branched along the first to fourth branch lines 142, 144, 146 and 148. Thus, the mixture gas may be divided into a first mixture gas flowing through the first branch line 142, a second mixture gas flowing through the second branch line 144, a third mixture gas flowing through the third branch line 146 and a fourth mixture gas flowing through the fourth branch line 148. The first mixture gas may be introduced into the first reaction chamber 120 through the first branch line 142. The second mixture gas may be introduced into the second reaction chamber 122 through the second branch line 144. The third mixture gas may be introduced into the third reaction chamber 124 through the third branch line 146. The fourth mixture gas may be introduced into the fourth reaction chamber 126 through the fourth branch line 148.

In order to uniformly hydrophobize the surfaces of the substrates in the first to fourth reaction chambers 120, 122, 124 and 126, it may be required to provide all of a hydrophobizing gas in the first mixture gas, a hydrophobizing gas in the second mixture gas, a hydrophobizing gas in the third mixture gas and a hydrophobizing gas in the fourth mixture gas with a uniform concentration. That is, when a concentration of the hydrophobizing gas in the first mixture gas, a concentration of the hydrophobizing gas in the second mixture gas, a concentration of the hydrophobizing gas in the third mixture gas and a concentration of the hydrophobizing gas in the fourth mixture gas may be different from each other, the surfaces of the substrates in the first to fourth reaction chambers 120, 122, 124 and 126 may not be uniformly hydrophobized.

The apparatus 100 may include a control module configured to provide the hydrophobizing gases in the first to fourth mixture gases flowing through the first to fourth branch lines 142, 144, 146 and 148 with the uniform concentration.

In example embodiments, the control module may include a mass flow controller (MFC) 160, first to fourth mass flow meters (MFM) 180, 182, 184 and 186, first to fourth valves 190, 192, 194 and 196 and a controller 200.

The MFC 160 may be installed on the gas line 130. The MFC 160 may be configured to measure a flux (i.e., a first flux) Qc of the carrier gas supplied to the mixture bath 110 through the gas line 130. Further, because the MFC 160 may include a valve installed in the MFC 160, the MFC 160 may be configured to control the flux Qc of the carrier gas.

The first to fourth MFMs 180, 182, 184 and 186 may be installed on the first to fourth branch lines 142, 144, 146 and 148. The first MFM 180 on the first branch line 142 may be configured to measure a flux (i.e., a second flux) Qm1 of the first mixture gas. The second MFM 182 on the second branch line 144 may be configured to measure a flux Qm2 of the second mixture gas. The third MFM 184 on the third branch line 146 may be configured to measure a flux Qm3 of the third mixture gas. The fourth MFM 186 on the fourth branch line 148 may be configured to measure a flux Qm4 of the fourth mixture gas.

The first valve 190 may be arranged between the first MFM 180 and the first reaction chamber 120 to control the flux Qm1 of the first mixture gas flowing through the first branch line 142. The second valve 192 may be arranged between the second MFM 182 and the second reaction chamber 122 to control the flux Qm2 of the second mixture gas flowing through the second branch line 144. The third valve 194 may be arranged between the third MFM 184 and the third reaction chamber 124 to control the flux Qm3 of the third mixture gas flowing through the third branch line 146. The fourth valve 196 may be arranged between the fourth MFM 186 and the fourth reaction chamber 126 to control the flux Qm4 of the fourth mixture gas flowing through the fourth branch line 148. In example embodiments, the first to fourth valves 190, 192, 194 and 196 may include a solenoid valve operated by an electronic signal, particularly, a piezo valve.

The controller 200 may be configured to receive the flux Qc of the carrier gas measured by the MFC 160. The controller 200 may be configured to receive the flux Qm1 of the first mixture gas measured by the first MFM 180, the flux Qm2 of the second mixture gas measured by the second MFM 182, the flux Qm3 of the third mixture gas measured by the third MFM 184 and the flux Qm4 of the fourth mixture gas measured by the fourth MFM 186.

When the flux Qc of the carrier gas supplied to the mixture bath 110 may be constant, fluxes Qv of the hydrophobizing gases flowing through the first to fourth branch lines 142, 144, 146 and 148 may be obtained by multiplying values by a conversion factor, which values may be obtained by subtracting by the flux Qc of the carrier gas from the fluxes Qm1, Qm2, Qm3 and Qm4 of the first to fourth mixture gases. For example, the flux Qv of the hydrophobizing gas may be obtained by following Formula (1).

Qvi=CF(Qmi−Qc) Formula (1)

Here, Qvi is the flux of the hydrophobizing gas flowing through the i-th branch line, CF is the conversion factor, and Qmi is the flux of the i-th mixture gas. The concentration C of the hydrophobizing gas may be obtained by following Formula (2).

Ci=Qvi/(Qc+Qvi) Formula (2)

Here, Ci is the concentration of the hydrophobizing gas in the i-th mixture gas. The controller 200 may control the first to fourth valves 190, 192, 194 and 196 based on the concentrations C of the hydrophobizing gases in the branch lines 142, 144, 146 and 148 obtained from Formula (2) to provide the hydrophobizing gases in the branch lines 142, 144, 146 and 148 with the uniform concentration.

Therefore, the hydrophobizing gases having the uniform concentration may uniformly hydrophobize the surfaces of the substrates in the reaction chambers 120, 122, 124 and 126. Thus, a hydrophobization difference of the surfaces of the substrates, i.e., a difference between contact angles may be decreased so that photoresist films coated on the surfaces of the substrates may have a uniform thickness. As a result, an error ratio of an exposure process may be decreased.

In example embodiments, the controller 200 may include a plurality of controllers 202, 204, 206 and 208 configured to individually control the first to fourth MFMs 180, 182, 184 and 186 and the first to fourth valves 190, 192, 194 and 196. That is, the controller 200 may include the first controller 202 configured to control the first MFM 180 and the first valve 190, the second controller 204 configured to control the second MFM 182 and the second valve 192, the third controller 206 configured to control the third MFM 184 and the third valve 194 and the fourth controller 208 configured to control the fourth MFM 186 and the fourth valve 196. Alternatively, the first to fourth MFMs 180, 182, 184 and 186 and the first to fourth valves 190, 192, 194 and 196 may be controlled by one controller 200.

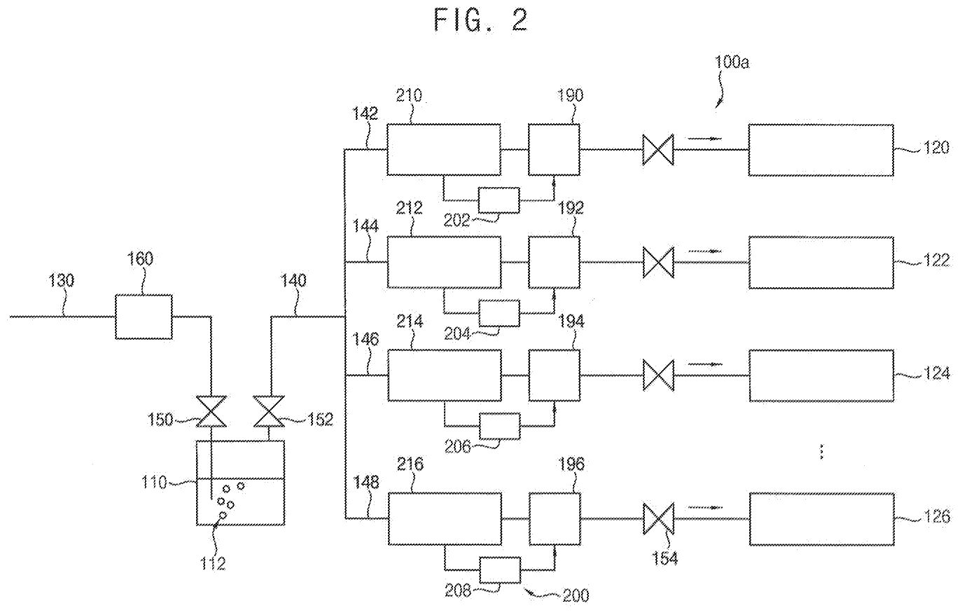

FIG. 2 is a block diagram illustrating an apparatus for processing a substrate in accordance with an example embodiment.

An apparatus 100a for processing a substrate in accordance with example embodiments may include elements substantially the same as those of the apparatus 100 in FIG. 1 except for a control module. Thus, the same reference numerals may refer to the same elements and any further illustrations with respect to the same elements may be omitted herein for brevity.

Referring to FIG. 2, a control module may include an MFC 160, first to fourth densitometers 210, 212, 214 and 216, first to fourth valves 190, 192, 194 and 196 and a controller 200. The MFC 160 and the first to fourth valves 190, 192, 194 and 194 in FIG. 2 may have functions substantially the same as those of the MFC 160 and the first to fourth valves 190, 192, 194 and 196 in FIG. 1, respectively. Thus, any further illustrations with respect to the functions of the MFC 160 and the first to fourth valves 190, 192, 194 and 196 in FIG. 2 may be omitted herein for brevity.

The first to fourth densitometers 210, 212, 214 and 216 may be arranged on the first to fourth branch lines 142, 144, 146 and 148. The first densitometer 210 on the first branch line 142 may be configured to measure the concentration or flux (i.e., second flux) of the hydrophobizing gas in the first mixture gas. The second densitometer 212 on the second branch line 144 may be configured to measure the concentration or flux of the hydrophobizing gas in the second mixture gas. The third densitometer 214 on the third branch line 146 may be configured to measure the concentration or flux of the hydrophobizing gas in the third mixture gas. The fourth densitometer 216 on the fourth branch line 148 may be configured to measure the concentration or flux of the hydrophobizing gas in the fourth mixture gas. In example embodiments, the first to fourth densitometers 210, 212, 214 and 216 may include an infrared densitometer.

The controller 200 may be configured to receive the flux (i.e., first flux) Qc of the carrier gas measured by the MFC 160. The controller 200 may be configured to receive the flux Qm1 of the first mixture gas measured by the first densitometer 210, the flux Qm2 of the second mixture gas measured by the second densitometer 212, the flux Qm3 of the third mixture gas measured by the third densitometer 214 and the flux Qm4 of the fourth mixture gas measured by the fourth densitometer 216.

The controller 200 may control the first to fourth valves 190, 192, 194 and 196 based on the concentrations C of the hydrophobizing gases or fluxes Qm1, Qm2, Qm3 and Qm4 of the first through fourth mixture gases in the branch lines 142, 144, 146 and 148 to provide the hydrophobizing gases in the branch lines 142, 144, 146 and 148 with the uniform concentration.

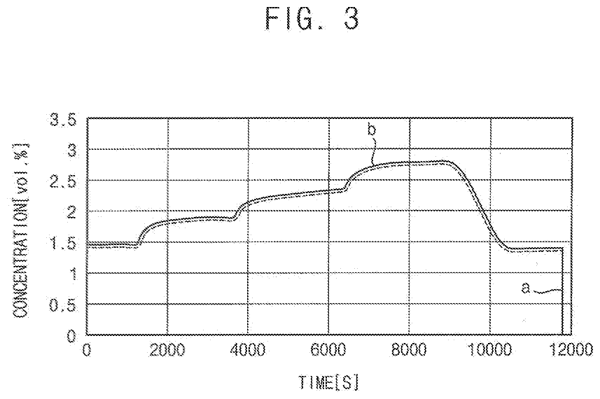

FIG. 3 is a graph showing concentrations of an HMDS gas measured by a densitometer and a mass flow meter. In FIG. 3, a horizontal axis may indicate a time, and a vertical axis may indicate a concentration. Further, in FIG. 3, a line a may represent a concentration of a hydrophobizing gas measured by a densitometer and a line b may represent a concentration of a hydrophobizing gas measured by a MFM.

As shown in FIG. 3, the line b may be substantially coincided with the line a. Thus, it can be noted that the concentration of the hydrophobizing gas obtained using the MFM may be substantially the same as the concentration of the hydrophobizing gas directly measured by the densitometer. As a result, the concentration of the hydrophobizing gas may be accurately measured using the MFM in FIG. 1.

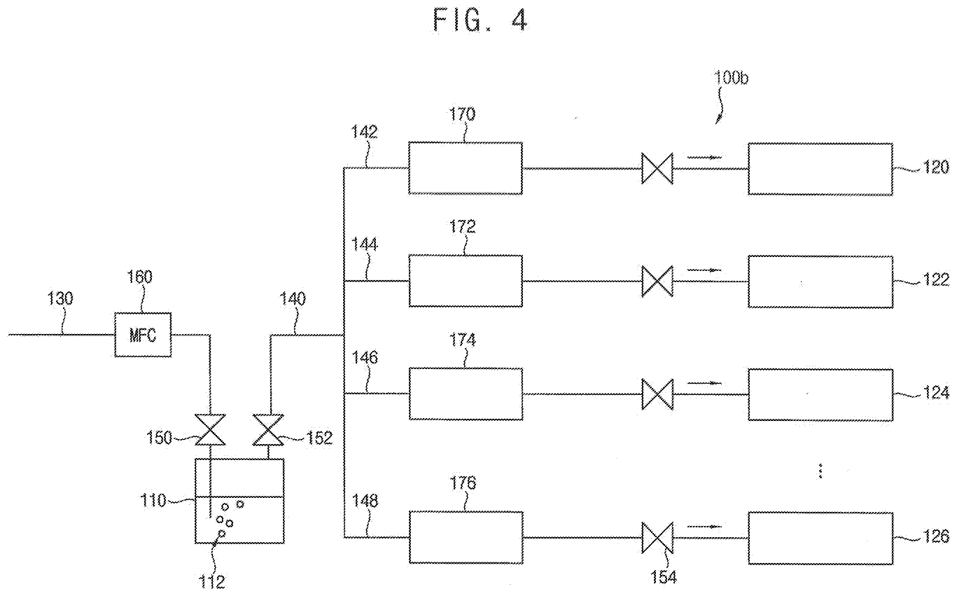

FIG. 4 is a block diagram illustrating an apparatus for processing a substrate in accordance with example embodiments.

An apparatus 100b for processing a substrate in accordance with example embodiments may include elements substantially the same as those of the apparatus 100 in FIG. 1 except for a control module. Thus, the same reference numerals may refer to the same elements and any further illustrations with respect to the same elements may be omitted herein for brevity.

Referring to FIG. 4, a control module may include a first MFC 160 and four MFCs 170, 172, 174 and 176.

The first MFC 160 may be installed on the gas line 130. The first MFC 160 may be configured to measure the flux (i.e., first flux) Qc of the carrier gas supplied to the mixture bath 110 through the gas line 130. Further, because the first MFC 160 may include a valve installed in the first MFC 160, the MFC 160 may be configured to control the flux Qc of the carrier gas.

The second MFCs 170, 172, 174 and 176 may be installed on the first to fourth branch lines 142, 144, 146 and 148. The second MFC 170 on the first branch line 142 may be configured to measure a flux (i.e., second flux) Qm1 of the first mixture gas. The second MFC 172 on the second branch line 144 may be configured to measure a flux Qm2 of the second mixture gas. The second MFC 174 on the third branch line 146 may be configured to measure a flux Qm3 of the third mixture gas. The second MFC 176 on the fourth branch line 148 may be configured to measure a flux Qm4 of the fourth mixture gas. Because the second MFCs 170, 172, 174 and 176 may include a valve, respectively, the second MFCs 170, 172, 174 and 176 may be configured to control the fluxes Qm1, Qm2, Qm3 and Qm4 of the first to fourth mixture gas.

When the flux Qc of the carrier gas supplied to the mixture bath 110 may be constant, the fluxes Qv of the hydrophobizing gases flowing through the first to fourth branch lines 142, 144, 146 and 148 may be obtained by multiplying values by a conversion factor, which values may be obtained by subtracting by the flux Qc of the carrier gas from the fluxes Qm1, Qm2, Qm3 and Qm4 of the first to fourth mixture gases. The concentrations of the hydrophobizing gases may be obtained from the fluxes Qv of the hydrophobizing gases using Formula (2).

The second MFCs 170, 172, 174 and 176 may control the first to fourth valves 190, 192, 194 and 196 based on the concentrations C of the hydrophobizing gases in the branch lines 142, 144, 146 and 148 to provide the hydrophobizing gases in the branch lines 142, 144, 146 and 148 with the uniform concentration.

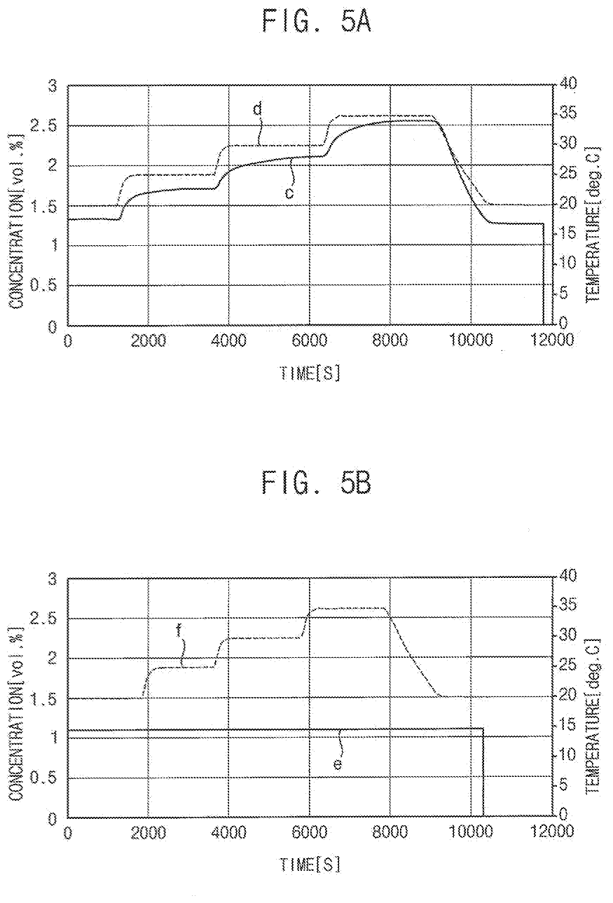

FIGS. 5A and 5B are graphs showing concentrations of HMDS gases in comparison to temperature changes of a bubbler in accordance with a related art apparatus (FIG. 5A) and in accordance with example embodiments (FIG. 5B). In FIGS. 5A and 5B, a horizontal axis may indicate a time, and a vertical axis may indicate a concentration. Further, in FIGS. 5A and 5B, lines c and e may represent a concentration of an HMDS gas and lines d and f may represent a temperature of a bubbler.

As shown in FIG. 5A, when the controls of the control module in accordance with example embodiments may not be performed, it can be noted that the concentration of the HMDS gas may be sharply changed in accordance with the temperature of the bubbler. In contrast, as shown in FIG. 5B, when the controls of the control module in accordance with example embodiments may be performed, it can be noted that the concentration of the HMDS gas may be constantly maintained regardless of the temperature of the bubbler.

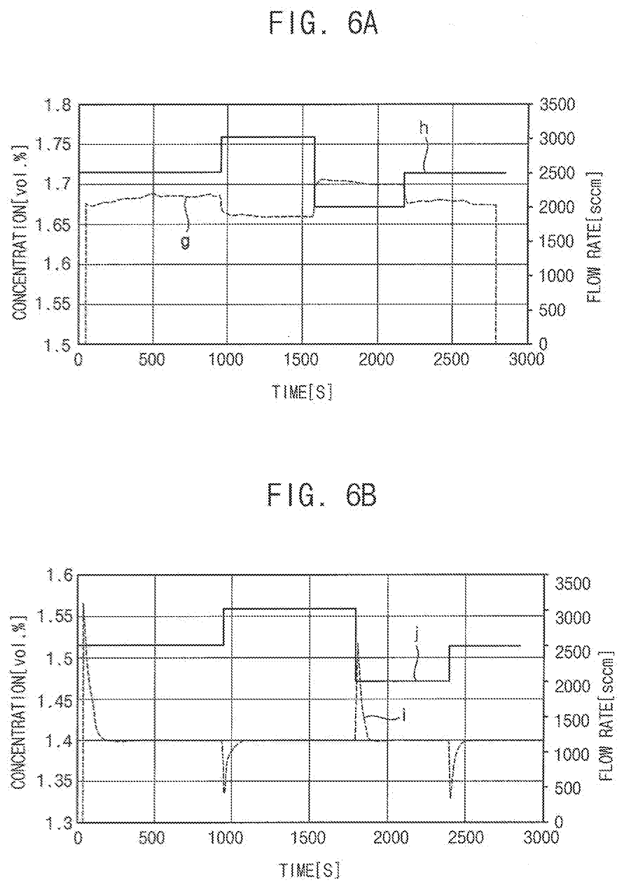

FIGS. 6A and 6B are graphs showing concentrations of HMDS gases in comparison to changes of a carrier gas flow rate (i.e., flux) in accordance with a related art apparatus (FIG. 6A) and in accordance with example embodiments (FIG. 6B). In FIGS. 6A and 6B, a horizontal axis may indicate a time, and a vertical axis may indicate a concentration. Further, in FIGS. 6A and 6B, lines g and i may represent a concentration of an HMDS gas and lines h and j may represent a flux of a carrier gas.

As shown in FIG. 6A, when the controls of the control module in accordance with example embodiments may not be performed, it can be noted that the concentration of the HMDS gas may be sharply changed in accordance with the flux of the carrier gas. In contrast, as shown in FIG. 6B, when the controls of the control module in accordance with example embodiments may be performed, it can be noted that the concentration of the HMDS gas may be substantially constantly maintained regardless of the flux of the carrier gas.

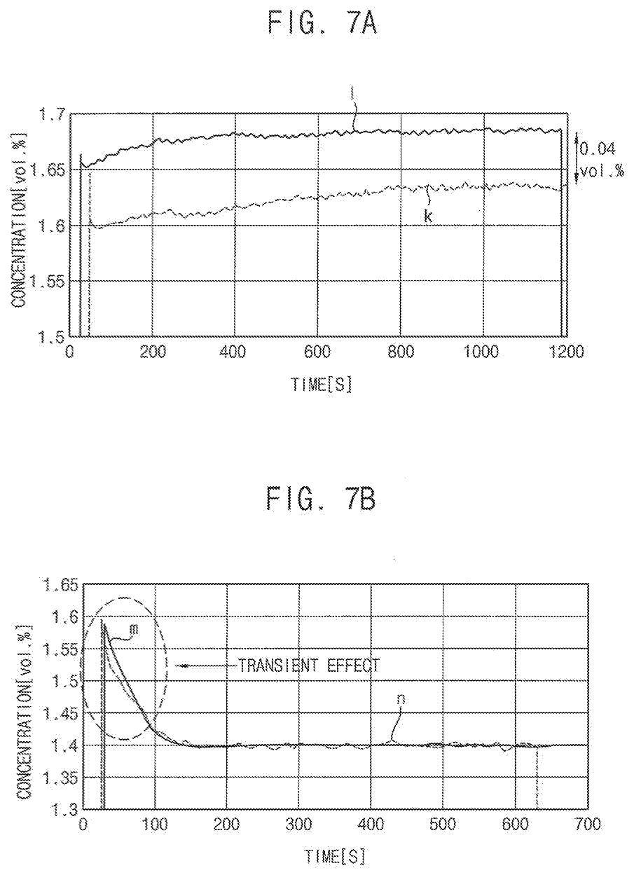

FIGS. 7A and 7B are graphs showing concentrations of HMDS gases in comparison to a surface height of a bubbler in accordance with a related art apparatus (FIG. 7A) and in accordance with example embodiments (FIG. 7B). In FIGS. 7A and 7B, a horizontal axis may indicate a time, and a vertical axis may indicate a concentration. Further, in FIGS. 7A and 7B, lines k and 1 may represent concentrations of an HMDS gas measured when the bubbler may have heights of about 40 mm and about 105 mm, respectively, and lines m and n may represent concentrations of an HMDS gas measured when the bubbler may have heights of about 40 mm and about 105 mm, respectively.

As shown in FIG. 7A, when the controls of the control module in accordance with example embodiments may not be performed, it can be noted that the concentrations of the HMDS gas may be greatly different from each other when the heights of the bubbler may be about 40 mm and about 105 mm. In contrast, as shown in FIG. 7B, when the controls of the control module in accordance with example embodiments may be performed, it can be noted that the concentrations of the HMDS gas may be constantly maintained regardless of the surface height of the bubbler.

According to example embodiments, the control module may control the fluxes of the mixture gas, particularly, the fluxes of the hydrophobizing gas supplied from the mixture bath to the reaction chambers to provide the hydrophobizing gas with a uniform concentration. Thus, a hydrophobization difference of the surfaces of the substrates, i.e., a difference between contact angles may be decreased so that photoresist films coated on the surfaces of the substrates may have a uniform thickness. As a result, an error ratio of an exposure process may be decreased.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the disclosure. Accordingly, all such modifications are intended to be included within the scope of the disclosure as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An apparatus for processing a substrate, the apparatus comprising:
a mixture bath configured to mix a plurality of chemicals to form a mixture;
a plurality of reaction chambers, each reaction chamber of the plurality of reaction chambers being configured to receive a respective substrate of a plurality of substrates to be processed by the mixture; and
a control module configured to control supply of the mixture to the plurality of reaction chambers from the mixture bath with a uniform concentration.

2. The apparatus of claim 1, wherein the control module comprises:
a first mass flow controller (MFC) configured to measure a first flux of a chemical of the plurality of chemicals supplied to the mixture bath; and
a plurality of second MFCs arranged between the mixture bath and the plurality of reaction chambers, the plurality of second MFCs being configured to measure second fluxes of the mixture supplied to the plurality of reaction chambers and to control the second fluxes of the mixture based on the first flux of the chemical measured by the first MFC and the second fluxes of the mixture measured by the plurality of second MFCs to provide the mixture with the uniform concentration.

3. The apparatus of claim 1, wherein the control module comprises:
a mass flow controller (MFC) configured to measure a first flux of a chemical of the plurality of chemicals supplied to the mixture bath;
a plurality of mass flow meters (MFMs) arranged between the mixture bath and the plurality of reaction chambers, the plurality of MFMs being configured to measure second fluxes of the mixture supplied to the plurality of reaction chambers;
a plurality of valves arranged between the plurality of MFMs and the plurality of reaction chambers; and
a controller configured to control the plurality of valves based on the first flux of the chemical measured by the MFC and the second fluxes of the mixture measured by the plurality of MFMs.

4. The apparatus of claim 3, wherein the plurality of valves comprise piezo valves.

5. The apparatus of claim 1, wherein the control module comprises:
a mass flow controller (MFC) configured to measure a first flux of a chemical of the plurality of chemicals supplied to the mixture bath;
a plurality of densitometers arranged between the mixture bath and the plurality of reaction chambers, the plurality of densitometers being configured to measure second fluxes of the mixture supplied to the plurality of reaction chambers;
a plurality of valves arranged between the plurality of densitometers and the plurality of reaction chambers; and
a controller configured to control the plurality of valves based on the first flux of the chemical measured by the MFC and the second fluxes of the mixture measured by the plurality of densitometers.

6. The apparatus of claim 5, wherein the plurality of densitometers comprise infrared densitometers and the plurality of valves comprise piezo valves.

7. The apparatus of claim 1, wherein the plurality of chemicals comprise:
a hydrophobizing solution received in the mixture bath to hydrophobize a surface of the substrate; and
a carrier gas for forming a hydrophobizing gas by evaporating the hydrophobizing solution.

8. The apparatus of claim 7, wherein the mixture bath comprises a bubbler configured to evaporate the hydrophobizing solution using the carrier gas.

9. The apparatus of claim 7, wherein each of the plurality of reaction chambers comprises a baking chamber configured to thermally treat the surface of the substrate using the hydrophobizing gas.

10. The apparatus of claim 7, wherein the hydrophobizing gas comprises a hexamethyldisilazane (HMDS) solution and the carrier gas comprises a nitrogen gas.

11. The apparatus of claim 1, further comprising:
a main line extended from the mixture bath; and
a plurality of branch lines branched from the main line and connected to the plurality of reaction chambers,
wherein the control module is installed on the plurality of branch lines.

12. The apparatus of claim 11, wherein the plurality of reaction chambers are vertically arranged and the plurality of branch lines are vertically arranged.

13. An apparatus for processing a substrate, the apparatus comprising:
a bubbler configured to evaporate a hydrophobizing solution using a carrier gas to form a mixture gas including a hydrophobizing gas and the carrier gas;
a plurality of baking chambers configured to thermally treat a plurality of substrates to be hydrophobized by the hydrophobizing gas;
a main line extended from the bubbler;
a plurality of branch lines branched from the main line and connected to the plurality of baking chambers; and
a control module configured to provide the hydrophobizing gas in the mixture gas flowing through the plurality of branch lines to the plurality of baking chambers with a uniform concentration.

14. The apparatus of claim 13, wherein the control module comprises:
a first mass flow controller (MFC) configured to measure a first flux of the carrier gas supplied to the bubbler; and
a plurality of second MFCs arranged on the plurality of branch lines, the plurality of second MFCs being configured to measure second fluxes of the mixture gas supplied to the plurality of baking chambers and to control the second fluxes of the mixture gas based on the first flux of the carrier gas measured by the first MFC and the second fluxes of the mixture gas measured by the plurality of second MFCs to provide the hydrophobizing gas with the uniform concentration.

15. The apparatus of claim 13, wherein the control module comprises:
a mass flow controller (MFC) configured to measure a first flux of the carrier gas suppled to the bubbler;
a plurality of mass flow meters (MFMs) arranged on the plurality of branch lines, the plurality of MFMs being configured to measure second fluxes of the mixture gas supplied to the plurality of baking chambers;
a plurality of piezo valves arranged between the plurality of MFMs and the plurality of baking chambers; and
a controller configured to control the plurality of piezo valves based on the first flux of the carrier gas measured by the MFC and the second fluxes of the mixture gas measured by the plurality of MFMs.

16. The apparatus of claim 13, wherein the control module comprises:
a mass flow controller (MFC) configured to measure a first flux of the carrier gas suppled to the bubbler;
a plurality of infrared densitometers arranged on the plurality of branch lines, the plurality of infrared densitometers being configured to measure second fluxes of the hydrophobizing gas in the mixture gas supplied to the plurality of baking chambers;
a plurality of piezo valves arranged between the plurality of infrared densitometers and the plurality of baking chambers; and
a controller configured to control the plurality of piezo valves based on the first flux of the carrier gas measured by the MFC and the second fluxes of the hydrophobizing gas measured by the plurality of infrared densitometers.

17. The apparatus of claim 13, wherein the hydrophobizing gas comprises a hexamethyldisilazane (HMDS) solution and the carrier gas comprises a nitrogen gas.

18. The apparatus of claim 13, wherein the plurality of baking chambers are vertically arranged and the plurality of branch lines are vertically arranged.

19. An apparatus for processing a substrate, the apparatus comprising:
a bubbler configured to evaporate a hexamethyldisilazane (HMDS) solution using a nitrogen gas to form a mixture gas including a HMDS gas and the nitrogen gas;
a plurality of baking chambers configured to thermally treat a plurality of substrates to be hydrophobized by the HMDS gas;
a main line extended from the bubbler;
a plurality of branch lines branched from the main line and connected to the plurality of baking chambers;
a mass flow controller (MFC) configured to measure a first flux of the nitrogen gas supplied to the bubbler;
a plurality of mass flow meters (MFMs) arranged on the plurality of branch lines, the plurality of MFMs being configured to measure second fluxes of the mixture gas supplied to the plurality of baking chambers;
a plurality of piezo valves arranged between the plurality of MFMs and the plurality of baking chambers; and
a control module configured to control the plurality of piezo valves based on the first flux of the nitrogen gas measured by the MFC and the second fluxes of the mixture gas measured by the plurality of MFMs to provide the HMDS gas with a uniform concentration.

20. The apparatus of claim 19, wherein the plurality of baking chambers are vertically arranged and the plurality of branch lines are vertically arranged.
